(19) United States
(12) Patent Application Publication
(10) Pub. No.: US 2006/0008584 A1
(43) Pub. Date: Jan. 12, 2006

(54) Method of forming carbon nanotube

(76) Inventors: Young-Jun Park, Suwon-si (KR); Jun-Hee Choi, Suwon-si (KR)

Correspondence Address: Robert E. Bushnell;Suite 300, 1522 K Street, N.W., Washington, DC, 20005, US

(21) Appl. No.: 10/910,565

(22) Filed: Aug. 4, 2004

(30) Foreign Application Priority Data
Nov. 26, 2003 (KR) 2003-84726

(51) Int. Cl. C23C 16/00; H01J 1/02

(52) U.S. Cl. 427/249.1; 313/309

(57) ABSTRACT

A method of forming a carbon nanotube whereby the carbon nanotube has a fine diameter. To form the carbon nanotube, a polyimide layer is formed on an electrode deposited on a substrate. A plurality of protrusions are formed on the electrode by etching the polyimide layer and the surface of the electrode. A catalyst layer is formed on the surface of the electrode between the protrusions. The carbon nanotube on the catalyst layer is grown. The carbon nanotubes have fine diameters so that the use of the carbon nanotube in a device may reduce the operating voltage and can improve a field emission characteristic of the device.

### CLAIM OF PRIORITY

This application claims all benefits accruing under 35 U.S.C. §119 from Korean Patent Application entitled “METHOD FOR FORMING CARBON NANOTUBE,” assigned serial No. 2003-84726 filed on Nov. 26, 2003, in the Korean Intellectual Property Office, the disclosure of which is incorporated herein in its entirety by reference.

### BACKGROUND OF THE INVENTION

1. Field of the Invention

The present invention relates to a method of forming a carbon nanotube, and more particularly, to a method of forming a carbon nanotube having a fine diameter using plasma.

2. Description of the Related Art

The main applications of display devices in information transfer media are monitors of personal computers and television screens. The display devices can be divided into cathode ray tubes (CRT), which use high speed thermionic emission, and flat panel displays. The flat panel displays include liquid crystal display (LCD) devices, plasma display panel (PDP) devices, and field emission display (FED) devices.

An FED device is a display device in which light is emitted from a fluorescent material of anodes due to the collision of electrons. The electrons are emitted from field emitters of cathodes to which a strong electric field is applied by a gate electrode.

A micro-tip composed of a metal such as molybdenum (Mo) is commonly used as the field emitter. Recently, carbon nanotube (CNT) emitters have been widely used. Since an FED device using a CNT emitter has advantages of a wide viewing angle, high resolution, low power consumption, and temperature stability, it is highly applicable to car navigation devices or view finders for electronic image displaying devices. Also, the FED device using the CNT emitter can be used as a monitor for a personal computer, a personal data assistant (PDA), a medical apparatus, or a high definition television. A CNT emitter can also be used as a field emitter for a backlight used in a liquid crystal device.

When forming a carbon nanotube, a chemical vapor deposition (CVD) method is generally used. More specifically, a catalyst metal layer can be formed to a predetermined thickness with a catalytic metal by magnetron sputtering or electron beam deposition on a surface of an electrode formed on a substrate. The carbon nanotube is grown vertically on a surface of the catalytic metal layer by injecting a H₂, N₂, or Ar gas together with a carbon containing gas such as CH₄, C₂H₂, C₂H₄, C₂H₆, CO, or CO₂ into a reaction chamber at a temperature of 500˜900° C. FIGS. 1A and 1B are scanning electron microscope (SEM) images of the surface of a catalytic metal layer and a carbon nanotube grown on the surface of the catalytic metal layer after heat treatment, respectively. Referring to FIG. 1A, particles with sizes of a few tens of nm are formed on the catalytic metal layer, and referring to FIG. 1B, the carbon nanotubes having the diameters corresponding to the sizes of the particles in FIG. 1A are formed.

The carbon nanotube can also be formed using a plasma enhanced chemical vapor deposition (PECVD). In this case, a SEM image of a surface of a catalytic metal layer before a carbon nanotube is grown is shown in FIG. 2. Referring to FIG. 2, the particles having almost the same sizes depicted in FIG. 1A are formed on the catalytic metal layer. And, the carbon nanotubes having the diameters corresponding to the sizes of each of particles are formed.

When forming the carbon nanotube by a conventional CVD method, the carbon nanotube has a relatively large diameter. If the diameter of the carbon nanotube is large, the operating voltage of a device including the carbon nanotube is large.

### SUMMARY OF THE INVENTION

It is therefore an object of the present invention to solve the above and/or other problems.

It is also an object of the present invention to provide an improved display device.

It is another object of the present invention to provide a method of forming a carbon nanotube having a fine diameter.

It is a further object of the present invention to provide a method of controlling a diameter of a carbon nanotube.

In order to achieve the above and other objectives, the first preferred embodiment of the method of forming a carbon nanotube on an electrode comprises forming a polyimide layer on the electrode, etching the polyimide layer and the electrode to form a plurality of protrusions on the electrode, forming a catalyst layer on the surface of the electrode between the protrusions, and forming the carbon nanotube on the catalyst layer.

It is preferred that the electrode is formed of molybdenum (Mo), chrome (Cr), and/or tungsten (W), and deposited to a thickness of 1,000˜10,000 Å using an electron beam evaporation method or a sputtering method.

The polyimide layer is preferably formed by coating polyimide on the electrode, soft-baking the polyimide, and curing the soft-baked polyimide. Preferably, the polyimide is coated on the electrode using a spin coating method or a method using surface tension. The polyimide is preferably soft-baked at a temperature of 95° C. and cured at a temperature of 350° C., and a thickness of the polyimide layer is preferably about 1 to about 10 μm, and more preferably a few μm.

A plurality of protrusions are formed on the surface of the polyimide layer formed on the electrode. The protrusions of the electrode are formed to a shape corresponding to the protrusions of the polyimide layer by etching the polyimide layer and the surface of the electrode. A gap between the protrusions of the electrode can be about 1 to about 50 nm, and more preferably a few nm.

It is preferred that the polyimide layer and the surface of the electrode are etched using a reactive ion etching (RIE) method. In the RIE method, plasma generated from a reaction gas that includes SF₆, O₂, or CHF₃ can be used.

The method may further comprise removing the polyimide remaining on the surface of the electrode before forming the catalyst layer.

The catalyst layer is preferably composed of at least one selected from the group consisting of W, Ni, Fe, Co, Y, Pd, Pt, and Au. The catalyst layer may be formed using a sputtering method or an electron beam evaporation method, and a thickness of the catalyst layer is 0.5˜2 nm.

The carbon nanotube is preferably formed using a thermal CVD method or a plasma enhanced CVD method. The carbon nanotube is grown on a surface of the catalyst layer using a gas containing carbon, and the carbon containing gas can be at least one selected from the group consisting of CH₄, C₂H₂, C₂H₄, C₂H₆, CO and CO₂.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1A is an SEM image of a heat treated surface of a catalytic metal layer for forming the carbon nanotube by a conventional CVD method;

FIG. 1B is an SEM image of the carbon nanotube grown by a conventional CVD method on the surface of the catalytic metal layer shown in FIG. 1A;

FIG. 2 is an SEM image of a surface of a catalytic metal layer before forming the carbon nanotube by a plasma enhanced CVD method;

FIGS. 3A through 3F are cross-sectional views for describing a method of forming the carbon nanotube according to an exemplary embodiment of the present invention;

FIG. 4 is an SEM image of a cross-sectional view of a polyimide layer formed on an electrode; and

FIG. 5 is an SEM image of a plurality of protrusions formed on an electrode.

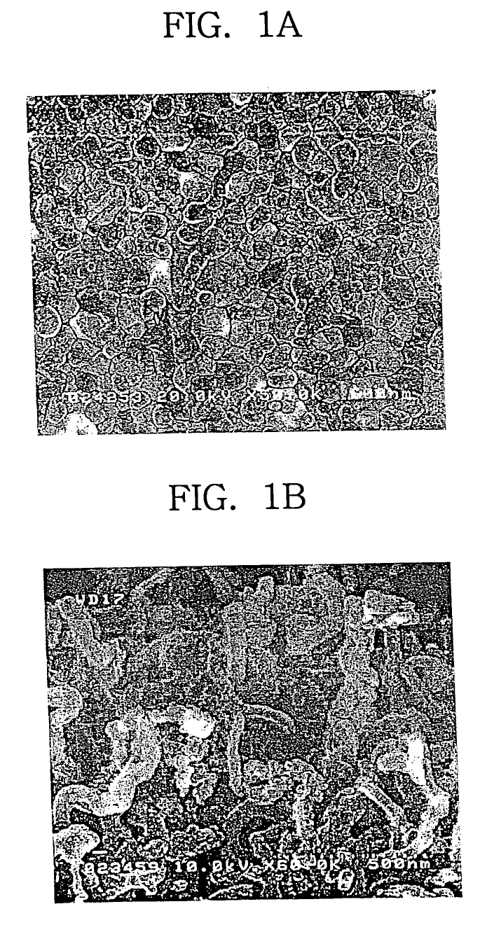

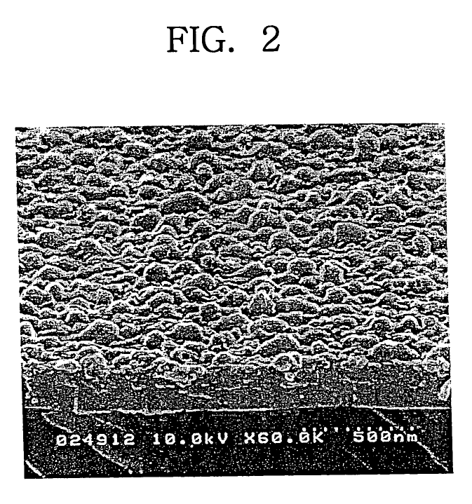

### DETAILED DESCRIPTION OF THE PREFERRED EMBODIMENTS

The present invention will now be described more fully with reference to the accompanying drawings in which exemplary embodiments of the invention are shown. Like reference numerals refer to like elements throughout the drawings.

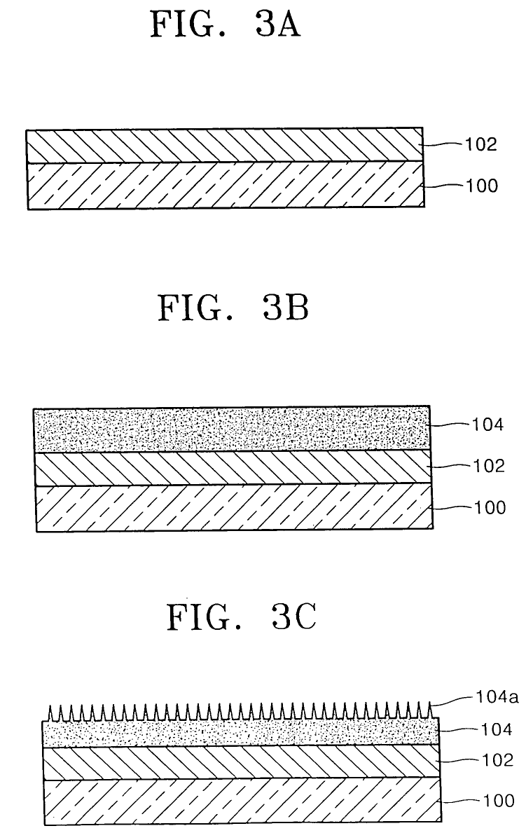

FIGS. 3A through 3F are cross-sectional views for describing a method of forming the carbon nanotube according to an exemplary embodiment of the present invention.

Referring to FIG. 3A, an electrode 102 is formed on a substrate 100 which is preferably composed of glass. The electrode 102 can be composed of molybdenum (Mo), chrome (Cr), or tungsten (W). The electrode can be deposited to a thickness of 1,000˜10,000 Å by electron beam evaporation or sputtering.

Referring to FIG. 3B, a polyimide layer 104 is formed on the electrode 102. Preferably, polyimide (Pl) is coated to a predetermined thickness on the electrode 102. Then, the polyimide coat is soft-baked and cured to form the polyimide layer 104. The polyimide is coated on the electrode 102 preferably to a thickness of approximately 1 to 10 μm, and more preferably a few μm by a spin coating method or a method using surface tension. The coated polyimide on the electrode 102 is soft-baked at a temperature of approximately 95° C., and the curing can be performed at a temperature of approximately 350° C. An organic material contained in the polyimide is removed in these processes.

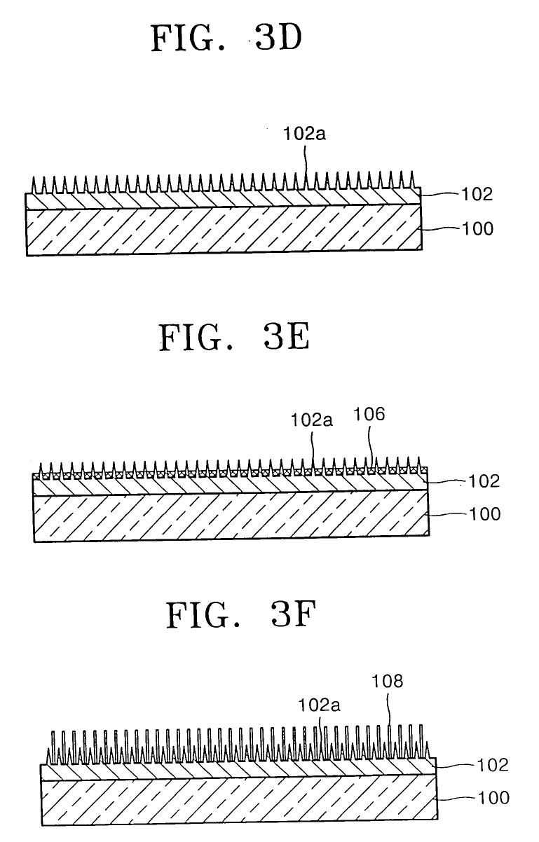

FIG. 4 is an SEM image of a cross-sectional view of the polyimide layer 104 formed on the electrode 102 and the substrate 100. Referring to FIG. 4, a plurality of tiny protrusions are observed on a surface of the polyimide layer 104.

Referring to FIG. 3C, by etching the polyimide layer 104, a plurality of protrusions 104a are formed on the surface of the polyimide layer 104. The polyimide layer 104 can be etched by a reactive ion etching (RIE) method. Preferably, the surface of the polyimide layer 104 is etched using plasma generated by a reaction gas injected into a reaction chamber. A reaction gas such as sulfur hexafluride (SF₆), oxygen, or trifluoromethane (CHF₃) with a flow rate of 7.5, 92.5, or 7.5 sccm (standard cubic centimeter per minute), respectively, is injected into the reaction chamber with a pressure of approximately 67.5 mtorr. The supplying power can be approximately 235 W.

The etching is continued until the upper surface of the electrode 102 is etched through the polyimide layer 104. Referring to FIG. 3D, a plurality of protrusions 102a corresponding to the protrusions 104a formed on the polyimide layer 104 are formed on the electrode 102. At this time, a gap between adjacent protrusions 102a on the surface of the electrode 102 is approximately 1 to 50 nm, and more preferably a few nm.

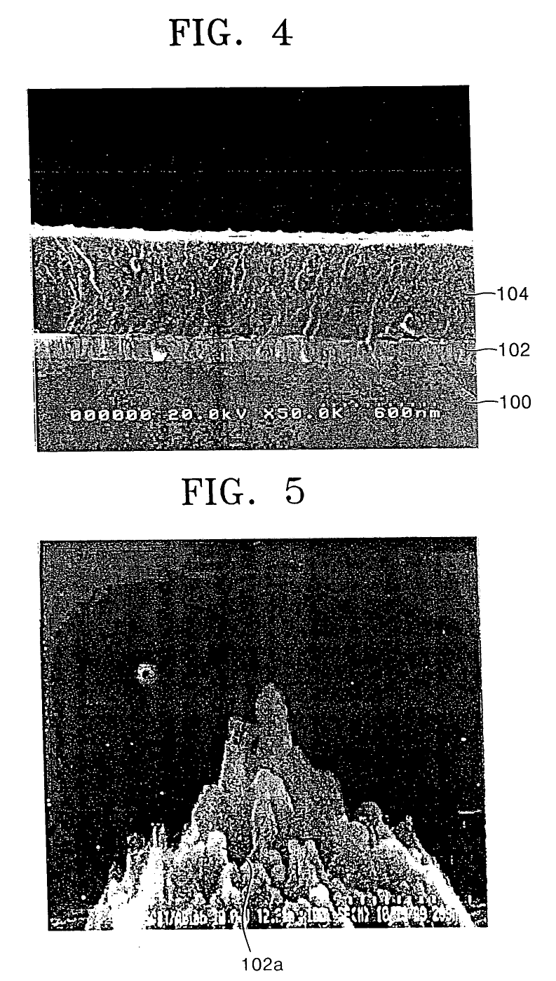

FIG. 5 is an SEM image of a plurality of protrusions 102a formed on the electrode 102. Referring to FIG. 5, a plurality of protrusions 102a corresponding to the protrusions 104a of the polyimide layer 104 are formed on the electrode 102.

Then, the surface of the electrode 102 is cleaned by removing the polyimide remaining between the protrusions 102a.

Next, referring to FIG. 3E, a catalyst layer 106 is formed between the protrusions 102a of the electrode 102. Preferably, the catalyst layer 106, on which carbon nanotubes can grow, is formed by depositing a catalyst on the surface of the electrode 102 using a sputtering method or an electron beam evaporation method. The catalyst layer 106 is formed only between the protrusions 102a of the electrode 102 because the catalyst layer 106 is formed relatively thin with a thickness of approximately 0.5˜2 nm. The catalyst can be at least one selected from the group consisting of W, Ni, Fe, Co, Y, Pd, Pt, and Au.

Referring to FIG. 3F, the carbon nanotube 108 is formed on a surface of the catalyst layer 106 using a thermal CVD method or a plasma enhanced CVD method. Preferably, while injecting a gas containing carbon into a reaction chamber, the gas of the chamber is maintained at approximately 500˜900° C., and the carbon nanotube is grown vertically from the surface of the catalyst layer 106. The carbon containing gas can be at least one selected from the group consisting of CH₄, C₂H₂, C₂H₄, C₂H₆, CO and CO₂. The carbon nanotube 108 grown in this way has a diameter of approximately 1 to 50 nm, and more preferably a few nm.

As described above, in the method of forming the carbon nanotube according to embodiments of the present invention, the carbon nanotube having a fine diameter can be produced by growing the carbon nanotube between protrusions formed on an electrode using plasma. Therefore, the use of the carbon nanotube in a device can reduce the operating voltage and can improve a field emission characteristic of the device.

While this invention has been particularly shown and described with reference to embodiments thereof, it will be understood by those skilled in the art that various changes in form and details may be made therein without departing from the spirit and scope of the invention as defined by the appended claims.

What is claimed is:

1. A method of forming a carbon nanotube, comprising:
depositing an electrode on a substrate;
forming a polyimide layer on the electrode;
etching the polyimide layer and the electrode to form a plurality of protrusions on the electrode;
forming a catalyst layer between the plurality of protrusions on the electrode; and
forming the carbon nanotube on the catalyst layer.

2. The method of claim 1, wherein the electrode comprises at least one selected from the group consisting of molybdenum (Mo), chrome (Cr), and tungsten (W).

3. The method of claim 1, wherein the step of depositing the electrode comprises using an electron beam evaporation method or a sputtering method.

4. The method of claim 1, wherein a thickness of the electrode is about 1,000 Å to about 10,000 Å.

5. The method of claim 1, wherein the step of forming the polyimide layer comprises the steps of coating polyimide on the electrode, soft-baking the polyimide, and curing the soft-baked polyimide.

6. The method of claim 5, wherein the step of coating the polyimide comprises using a spin coating method or a method using surface tension.

7. The method of claim 5, wherein the step of soft-baking the polyimide is performed at a temperature of 95° C. and the step of curing the soft-baked polyimide is performed at a temperature of 350° C.

8. The method of claim 1, wherein a thickness of the polyimide layer is approximately 1 to 10 μm.

9. The method of claim 1, wherein a thickness of the polyimide layer is a few μm.

10. The method of claim 1, wherein the polyimide layer formed on the electrode has a plurality of protrusions on the surface of the polyimide layer.

11. The method of claim 10, wherein the plurality of protrusion of the electrode has a shape corresponding to the plurality of protrusions of the polyimide layer.

12. The method of claim 1, wherein a gap between the adjacent protrusions of the electrode is approximately 1 to 50 nm.

13. The method of claim 1, wherein a gap between the adjacent protrusions of the electrode is a few nm.

14. The method of claim 1, wherein the step of etching the polyimide layer and the electrode comprises using a reactive ion etching method.

15. The method of claim 14, wherein the reactive ion etching method comprises using plasma generated from a reaction gas.

16. The method of claim 15, wherein the reaction gas includes at least one selected from the group consisting of SF₆, O₂, and CHF₃.

17. The method of claim 1, further comprising removing the polyimide remaining on the surface of the electrode before forming the catalyst layer.

18. The method of claim 1, wherein the catalyst layer comprises at least one selected from the group consisting of W, Ni, Fe, Co, Y, Pd, Pt, and Au.

19. The method of claim 1, wherein the step of forming the catalyst layer comprises using a sputtering method or an electron beam evaporation method.

20. The method of claim 1, wherein a thickness of the catalyst layer is 0.5 nm to 2 nm.

21. The method of claim 1, wherein the step of forming the carbon nanotube comprises using a method selected from the group consisting of a thermal chemical vapor deposition method and a plasma enhanced chemical vapor deposition method.

22. The method of claim 21, wherein the step of forming the carbon nanotube comprises growing the carbon nanotube by using a gas containing carbon.

23. The method of claim 22, wherein the carbon containing gas is at least one selected from the group consisting of CH₄, C₂H₂, C₂H₄, C₂H₆, CO and CO₂.

24. The display device comprising the carbon nanotube prepared by the method of claim 1.

25. The display device of claim 24, wherein a diameter of the carbon nanotube is approximately 1 to 50 nm.

26. The display device of claim 24, wherein a diameter of the carbon nanotube is a few nm.

27. A method of forming a carbon nanotube on an electrode, comprising:
forming a polyimide layer on the electrode, a surface of said polyimide layer having a first plurality of protrusions;
etching the polyimide layer on the electrode until the surface of the electrode has a second plurality of protrusions corresponding to said first plurality of protrusions;
forming a catalyst layer between the second plurality of protrusions; and
growing the carbon nanotube on the catalyst layer.

28. The method of claim 27, wherein the step of etching the polyimide layer comprises using plasma generated from a reaction gas.

29. A method of controlling a diameter of a carbon nanotube on an electrode, comprising:
setting an average diameter of the carbon nanotube to be formed;
forming a plurality of protrusions on the electrode, wherein an average distance between the adjacent protrusions is substantially equal to the set average diameter of the carbon-nanotube to be formed;
forming a catalyst layer between said plurality of protrusions on the electrode; and
growing the carbon nanotube on the catalyst layer to provide the carbon nanotube having an average diameter substantially equal to the average distance between the adjacent protrusions of the electrode.

30. The method of claim 29, wherein said step of forming the plurality of protrusions on the electrode comprises the steps of:
forming a polyimide layer having a plurality of protrusions on the surface of the polyimide layer; and
etching the polyimide layer on the electrode until the surface of the electrode has the plurality of protrusions corresponding to the plurality of protrusions of the polyimide layer.

31. The method of claim 30, wherein the step of forming the plurality of protrusions on the electrode comprises using plasma generated from a reaction gas.
